(19) United States
(12) Patent Application Publication
(10) Pub. No.: US 2025/0112130 A1
(43) Pub. Date: Apr. 3, 2025

(54) FLAT SEMICONDUCTOR PACKAGE WITH COPLANAR LEADS

(71) Applicant: PANJIT INTERNATIONAL INC., Kaohsiung City (TW)

(72) Inventors: CHUNG-HSIUNG HO, Kaohsiung City (TW); CHI-HSUEH LI, Tainan City (TW)

(21) Appl. No.: 18/527,703

(22) Filed: Dec. 4, 2023

(30) Foreign Application Priority Data
Sep. 28, 2023 (TW) 112137410

(51) Int. Cl. H01L 23/495; H01L 21/48; H01L 23/00; H01L 23/31

(52) U.S. Cl. CPC H01L 23/49541; H01L 21/4842; H01L 23/3107; H01L 23/49503; H01L 23/49582; H01L 24/48; H01L 2224/48247; H01L 2924/181

(57) ABSTRACT

A flat semiconductor package includes a die pad, a die attached on the die pad, multiple leads distributed around the die pad and electrically connected to the die, and an encapsulant layer covering the die pad, the die and the leads. The encapsulant layer has a flat cuboid configuration having side surfaces from which the multiple leads laterally extend without being bent. Bottom surfaces of the die pad, the multiple leads and the encapsulant layer are coplanar. Manufacturing of the flat semiconductor package prevents the use of specific machines for encapsulant molding, punching and lead bending. When the leads are soldered onto a circuit board, more solder adhere on each lead laterally extending from the flat semiconductor package. Further, the stress accumulated on the leads is less and the reliability of the flat semiconductor package can be improved.

### CROSS REFERENCE TO RELATED APPLICATIONS

This non-provisional application claims the benefit under 35 U.S.C. § 119(a) to Patent Application No. 112137410 filed in Taiwan on Sep. 28, 2023, which is hereby expressly incorporated by reference into the present application.

### BACKGROUND OF THE INVENTION

### 1. Field of the Invention

The present invention relates to a flat semiconductor package, particularly to a flat semiconductor package with coplanar leads.

### 2. Description of the Related Art

Manufacturing of a conventional semiconductor package may involve usual steps of die attaching, wire bonding, molding, trimming, and lead forming. With reference to FIG. 8, after the die attaching, wire bonding and molding processes, a plurality of semi-finished semiconductor packages 82 have been formed on a lead frame 81.

With reference to FIG. 9, the lead frame 81 is punched to obtain multiple separated semiconductor packages 82. Each semiconductor package 82 may have multiple leads 83 extending laterally outward. With further reference to FIG. 10, the leads 83 of each semiconductor package 82 need to be bent in a specific shape such as L-shape and J-shape by demand.

However, when manufacturing different semiconductor packages in distinct shapes, processing machines and molds may be only exclusive to specific types of semiconductor packages. For example, in the molding process for embedding the chip into encapsulant, the lead frame must be held in a specific mold with multiple specific cavities for accommodating the chips so that the encapsulant can be injected into each cavity to embed the respective chip. For another semiconductor package in which the number, size and position of the chips and leads have been altered, the original molding machine may not be applicable for such semiconductor package.

After demolding process, the semiconductor packages taken out from the molding machine may have overflowed encapsulant remaining thereon, such that an additional trimming process to remove residual is necessary.

When subsequently punching the lead frame and bending the leads of each semiconductor package to form a specific shape, such processes also involve many punching and lead-trimming machines, resulting in high equipment cost.

Because the leads of each semiconductor package have been treated through multiple mechanical processing steps such as punching and bending, extra stress will be accumulated on these leads, which may accordingly cause failure problems of the leads.

### SUMMARY OF THE INVENTION

An objective of the present disclosure is to provide a flat semiconductor package with coplanar leads for enhancing product reliability and reducing manufacturing cost.

The flat semiconductor package comprises:
a die pad having a top surface and a bottom surface;
a die attached on the top surface of the die pad;
multiple leads distributed around the die pad and electrically connected to the die; each lead having a top surface, a bottom surface, two opposite side surfaces, and an end surface; and
an encapsulant layer covering the die pad, the die and a portion of each lead, the encapsulant layer having a top surface, a bottom surface and four side surfaces and;
wherein all of the top surface, the bottom surface, the four side surfaces of the encapsulant layer are flat surfaces;
the two four surfaces of the encapsulant surface are perpendicular to the top surface and the bottom surface of the encapsulant surface; and
the multiple leads laterally protrude from the encapsulant layer without being bent.

According to the present invention, conventional manufacturing processing steps such as molding, lead frame punching, trimming and lead bending are omitted to save manufacturing cost. By comprehensively applying the encapsulant layer on the lead frame, the problem of residual encapsulant on each finished package can be avoided. Without performing the mechanical punching, lead bending processes, etc., the stress accumulated on the leads May be reduced to improve product reliability.

Other objectives, advantages and novel features of the invention will become more apparent from the following detailed description when taken in conjunction with the accompanying drawings.

### BRIEF DESCRIPTION OF THE DRAWINGS

FIG. 1A is a cross sectional view of a semi-finished substrate in accordance with the present invention;

FIG. 1B is a perspective view of the semi-finished substrate of FIG. 1;

FIG. 2A is a cross sectional view showing a pre-cutting process performed on the semi-finished substrate along one direction;

FIG. 2B is a perspective view of the semi-finished substrate of FIG. 2A;

FIG. 2C is an enlarged perspective view showing a portion of the semi-finished substrate of FIG. 2B;

FIG. 3A is a perspective view showing a pre-cutting process performed on the semi-finished substrate along two different directions;

FIG. 3B is an enlarged perspective view showing a portion of the semi-finished substrate of FIG. 2B;

FIG. 4 is a perspective view showing a portion of the semi-finished substrate, wherein encapsulant between adjacent leads is removed;

FIG. 5 is a perspective view showing a portion of the semi-finished substrate covered by a masking layer for removing encapsulant between adjacent leads by plasma;

FIG. 6 is a perspective view showing a full-cutting process performed on the semi-finished substrate;

FIG. 7A is a top perspective view of a flat semiconductor package of the present invention;

FIG. 7B is a bottom perspective view of the flat semiconductor package of the present invention;

FIG. 7C is a cross sectional view of the flat semiconductor package of the present invention;

FIG. 8 is a perspective view showing a lead frame with a plurality of semi-finished semiconductor packages in accordance with prior art;

FIG. 9 shows the lead frame being separated from the plurality of semi-finished semiconductor packages in FIG. 8; and

FIG. 10 is a perspective view of an end productor of the semiconductor package with bent leads in FIG. 9.

### DETAILED DESCRIPTION OF THE INVENTION

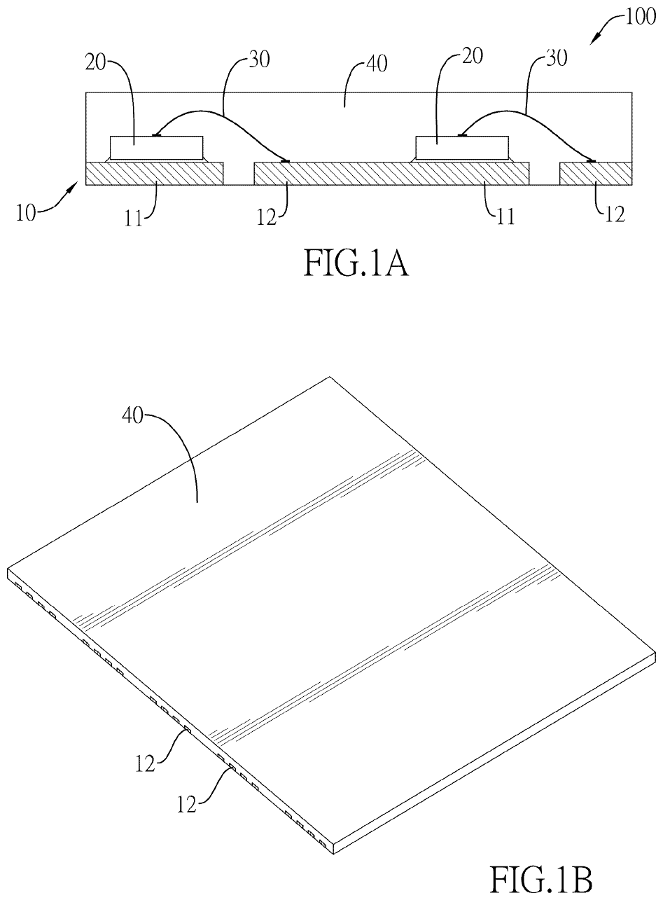

With reference to FIGS. 1A and a 1B, a semi-finished substrate 100 having a plurality of semi-finished semiconductor packages is manufactured through processes including die attaching, wire bonding, molding, etc. The semi-finished substrate 100 comprises a lead frame 10 having multiple die pads 11 and leads 12, wherein the multiple die pads 11 are arranged in a line or in a matrix configuration. The multiple leads 12 are distributed around each die pad 11. For each semiconductor package, one or more than one die pad 11 may be included, and at least one die 20 is electrically attached on each die pad 11 and electrically connected to the respective leads 12 through connectors 30. The connectors 30 may comprise, but not limited to, conductive wires, conductive clips, etc.

An encapsulant layer 40 with a thickness enough to cover the lead frame 10, the dies 20 and the connectors 30 is provided on the lead frame 10. Different to conventional molding process, the encapsulant layer 40 comprehensively covers the lead frame 10 and all the leads 12, rather than encapsulates an individual die and die pad as prior art does. After forming the encapsulant layer 40, the encapsulant layer 40 has a relatively flat top surface.

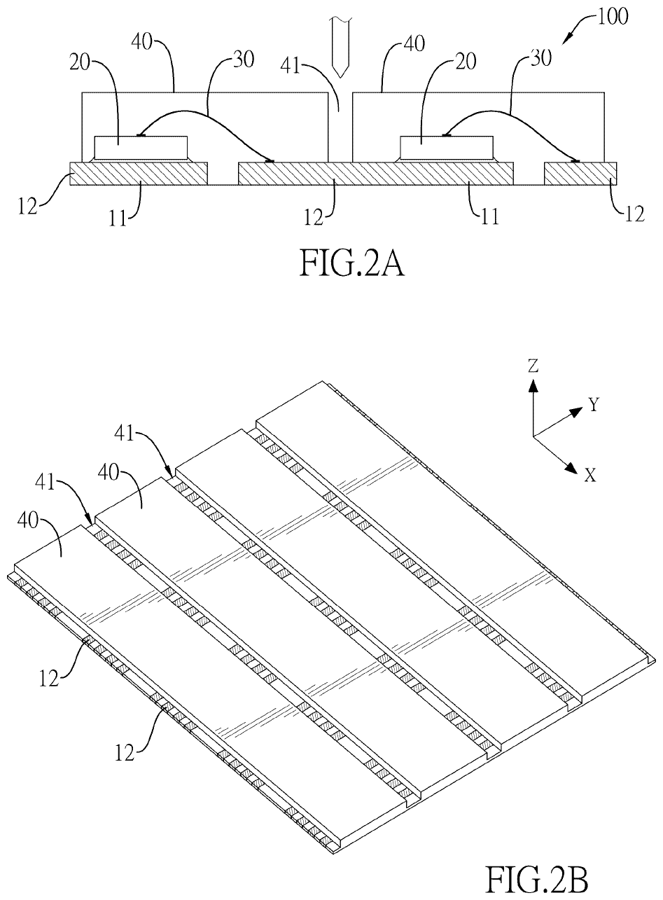

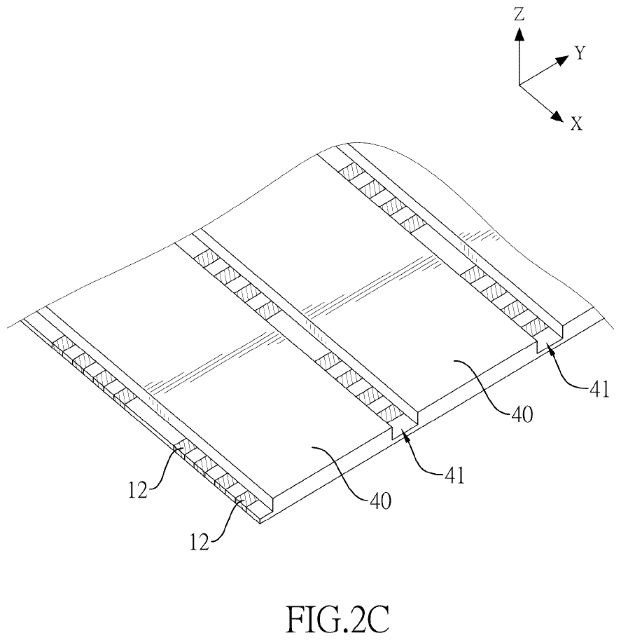

With reference to FIGS. 2A to 2C, a pre-cutting process is performed to cut the encapsulant layer 40 to form multiple pre-cutting grooves 41 on the top surface of the encapsulating layer 40. Each of the pre-cutting grooves 41 and each of the leads 12 respectively extend along a first direction and a second direction perpendicular to each other. For example, in the embodiment shown in FIG. 2B, all the leads 12 protrude from two opposite sides of each semi-finished semiconductor package and extend along the Y-axis. The pre-cutting grooves 41 will be formed along the X-axis. Each of the pre-cutting grooves 41 is formed from the top surface of the encapsulant layer 40 downward to an upper surface of each lead 12. The upper surface of each lead 12 is exposed from the pre-cutting grooves 41, wherein each lead 12 is not cut through in the pre-cutting process. The pre-cutting process may be implemented by, for example, sawing blades or laser cutting.

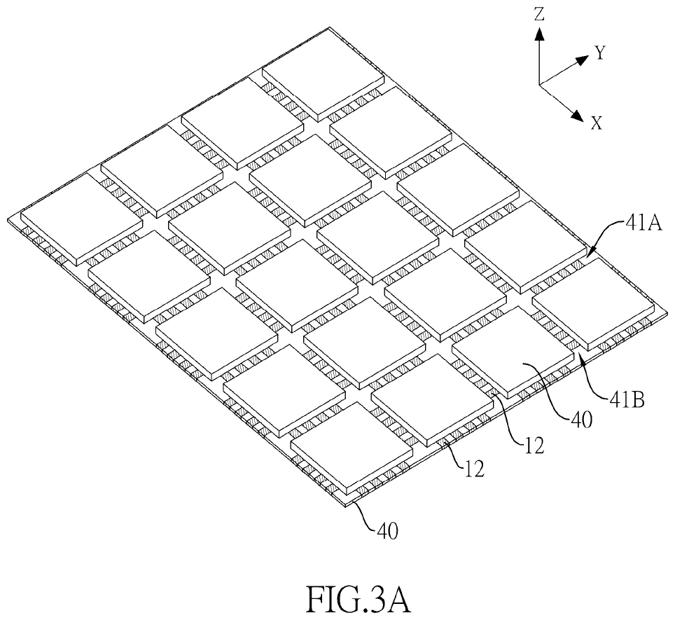

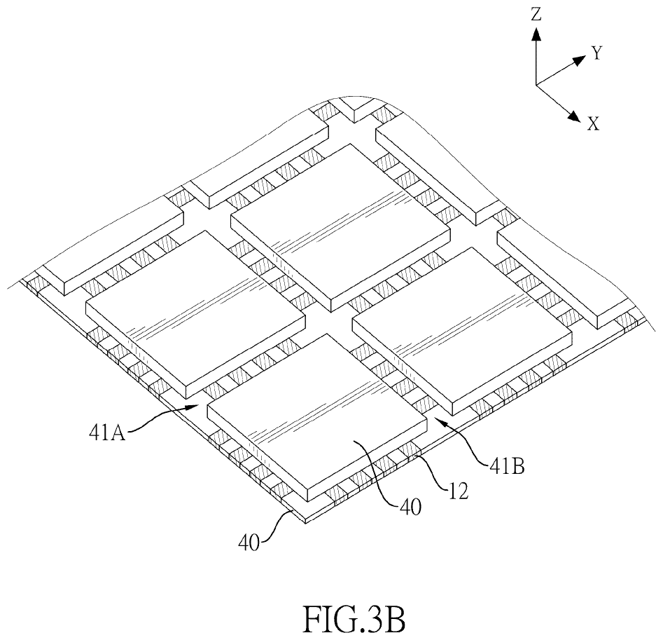

With reference to FIGS. 3A to 3B, in another embodiment, the leads 12 of each semi-finished semiconductor package extend outward from four side surfaces of the semi-finished semiconductor package. The pre-cutting grooves 41A along the Y-axis intersect the pre-cutting grooves 41B along the X-axis formed on the encapsulant layer 40.

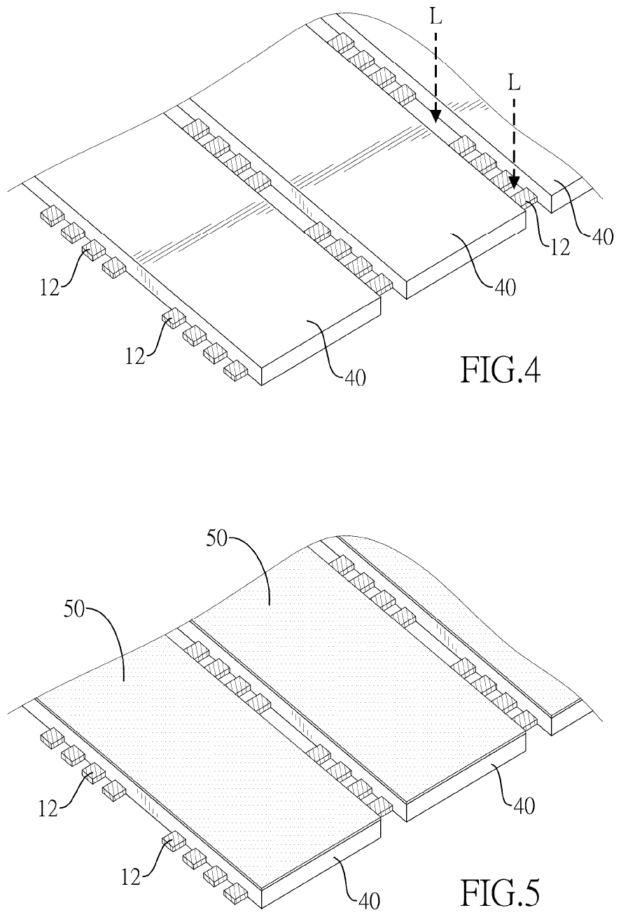

With reference to FIG. 4, after the pre-cutting process, the encapsulant layer 40 which fills between each two adjacent leads 12 is removed. Laser beam L is preferably applied to remove the encapsulant layer 40 filling between each two adjacent leads 12. By controlling the laser beam to irradiate in the pre-cutting grooves 41, the encapsulant layer 40 made of dielectric material can be burned by the laser beam without harming the leads 12. When the dielectric material filling between adjacent leads 12 has been removed, a gap is formed between each two adjacent leads 12.

In accordance with another embodiment, plasma etching technique may be used to remove the encapsulant layer 40 filling between each two adjacent leads 12. With reference to FIG. 5, when using the plasma etching technique, a mask layer 50 is provided over the top surface of the encapsulant layer 40. Only the encapsulant layer 40 in the pre-cutting grooves 41 is uncovered by the mask layer 50. The mask layer 50 protects the top surface of the encapsulant layer 40 from being etched. Since the dielectric material of the encapsulant layer 40 filling in the pre-cutting grooves 41 is exposed in the plasma etching reaction space, the dielectric material between each two adjacent leads 12 can be removed by plasma gas mixture.

After the plasma etching process, the mask layer 50 may remain on or be removed from the encapsulant layer 40 by demand. In an embodiment of the plasma etching process, the mask layer 50 is made of a metal layer and remains on the semiconductor package as a heat-dissipating layer to improve surface heat dissipation efficiency of the semiconductor package.

After removing the encapsulant layer 40 between each adjacent two leads 12, a plating process may be optionally performed to form a tin layer 60 on the exposed surfaces of each lead 12 to reduce the area of surface oxidation.

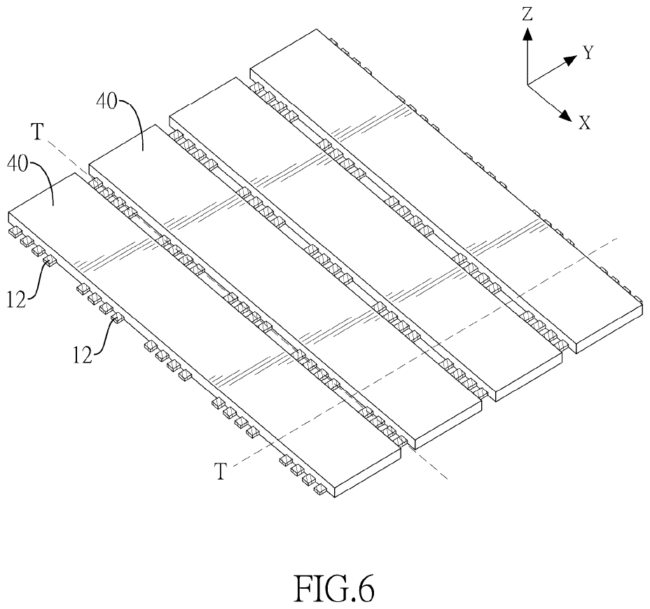

With reference to FIG. 6, a full-cutting process is performed along cutting paths T as indicated by broken lines around the semiconductor packages to obtain a plurality of separated semiconductor packages. In an example, the full-cutting process is performed along at least the pre-cutting grooves 41 to separate the leads 12 of neighboring semiconductor packages.

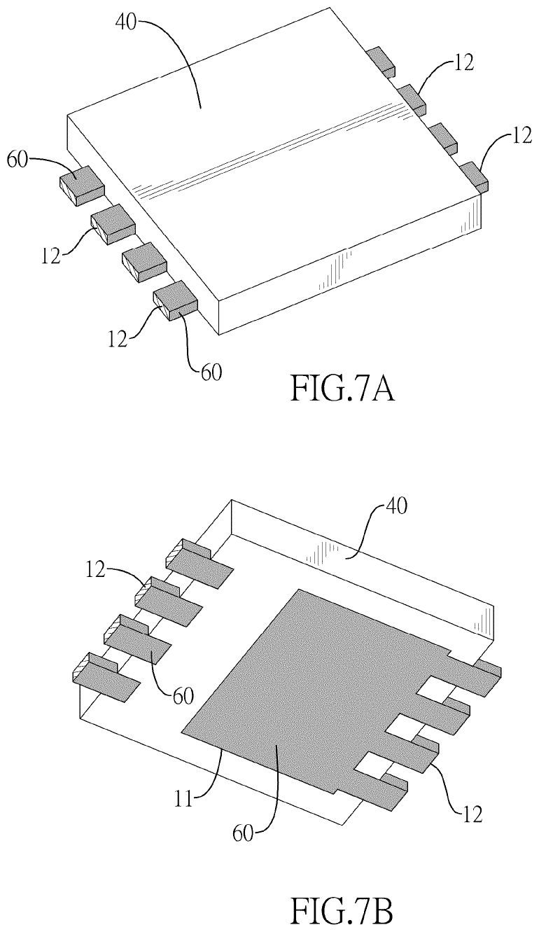

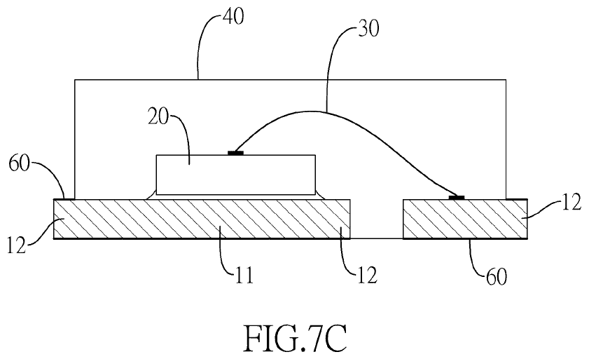

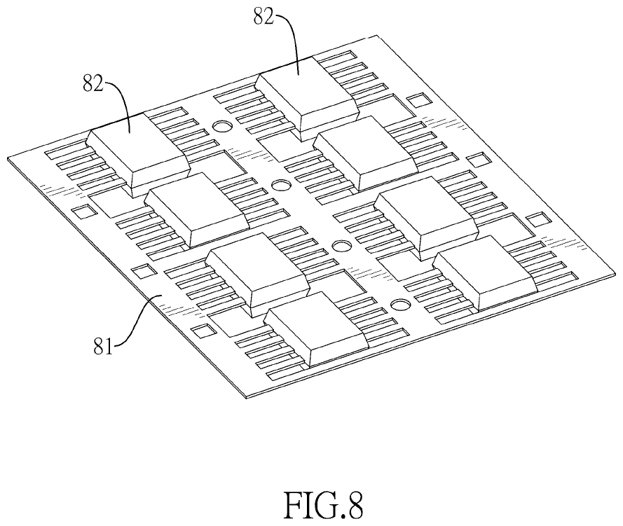

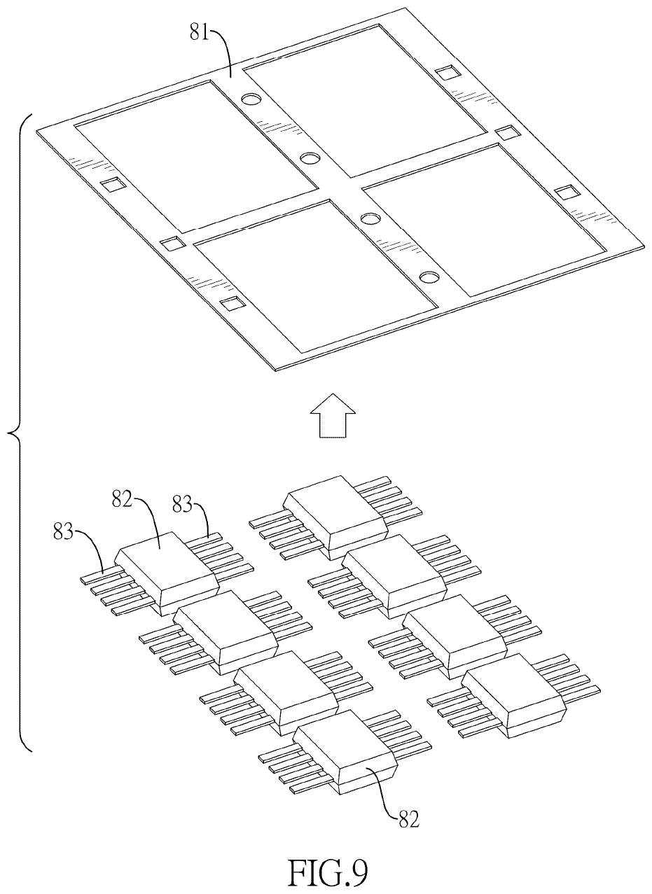

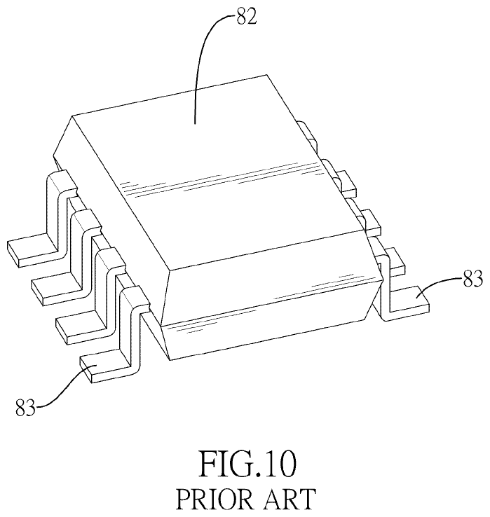

With reference to FIGS. 7A to 7C, a flat semiconductor package in accordance with the present invention comprises a die pad 11, multiple leads 12, and a die 20 attached on a top surface of the die pad 11 and electrically connected to the leads 12 through the connectors 30. An encapsulant layer 40 covers the die pad 11, the multiple leads 12, the die 20 and the connectors 30. The encapsulant layer 40 is a substantial flat cuboid configuration with six surfaces, including a top surface, a bottom surface and four side surfaces, wherein each side surface is a flat surface and is perpendicularly flush with the top surface and the bottom surface without a draft angle.

Each lead 12 is a straight lead without being bent and laterally protrudes from two opposite sides surfaces of the encapsulant layer 40. Each lead 12 has a bottom surface, a top surface, two opposite side surfaces and an end surface. The bottom surfaces of all the leads 12, the die pad 11 and the encapsulant layer 40 are coplanar. Accordingly, the bottom surfaces of all the leads 12 as well as the bottom surface of the die pad 11 are exposed from the encapsulant layer 40 without being covered. The bottom surface, the top surface and the two opposite side surfaces of each lead 12 can be covered by a tin layer 60 thereon. The end surface of each lead 12 is formed through full-cutting process so that no tin layer 60 is formed thereon.

In an application of the flat semiconductor package, the bottom surface of each lead 12 is adapted to be electrically attached onto a circuited board. Each lead 12 protruding from the encapsulant layer 40 is solderable on the circuit board. By inspecting the solder distributed on the leads 12, the reliability of electrical connection can be easily inspected from the outside of the semiconductor package for determining whether it is well soldered to the circuit board

In short, the flat semiconductor package in accordance with the present invention has the features as follows.
1. In comparison to conventional packaging process, the exclusive molding equipment for molding the lead frame and a specific lead trimming machine are omitted so that the manufacturing cost is reduceable.
2. By providing the encapsulant layer comprehensively on the lead frame instead of covering individual die pad, the efficiency of the molding process would be improved and the problem of overflowed encapsulant is avoided.
3. In accordance with one embodiment, the flat semiconductor package of the present invention has a configuration like the quad-flat no-lead (QFN) package with bottom contacts for soldering. Furthermore, each lead laterally extends from the flat semiconductor package, which can increase the area in contact with the solder, enhance reliability of soldering connection with a circuit board, and allow to inspect the electrical connection quality according to solder appearance around the flat semiconductor package.
4. Without performing the mechanical punching and lead bending processes, less stress may be accumulated on the leads.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. A flat semiconductor package comprising:
a die pad having a top surface and a bottom surface;
a die attached on the top surface of the die pad;
multiple leads distributed around the die pad and electrically connected to the die, each lead having a top surface, a bottom surface, two opposite side surfaces, and an end surface; and
an encapsulant layer covering the die pad, the die and a portion of each lead, the encapsulant layer having a top surface, a bottom surface and four side surfaces;
wherein all of the top surface, the bottom surface, the four side surfaces of the encapsulant layer are flat surfaces;
the four side surfaces of the encapsulant layer are perpendicular to the top surface and the bottom surface of the encapsulant layer; and
the multiple leads laterally protrude from the encapsulant layer without being bent.

2. The flat semiconductor package as claimed in claim 1, wherein the encapsulant layer has a substantial flat cuboid configuration; and
the bottom surfaces of the multiple leads, the bottom surface of the encapsulant layer and the bottom surface of the die pad are coplanar.

3. The flat semiconductor package as claimed in claim 2, wherein the multiple leads are electrically connected to the die through conductive wires.

4. The flat semiconductor package as claimed in claim 2, wherein the multiple leads are electrically connected to the die through conductive clips.

5. The flat semiconductor package as claimed in claim 1, wherein a tin layer is formed on the top surface, the bottom surface and the two opposite side surfaces of each lead; and
the end surface of each lead is formed by cutting and not covered by the tin layer.

6. The flat semiconductor package as claimed in claim 2, wherein a tin layer is formed on the top surface, the bottom surface and the two opposite side surfaces of each lead; and
the end surface of each lead is formed by cutting and not covered by the tin layer.

7. The flat semiconductor package as claimed in claim 3, wherein a tin layer is formed on the top surface, the bottom surface and the two opposite side surfaces of each lead; and
the end surface of each lead is formed by cutting and not covered by the tin layer.

8. The flat semiconductor package as claimed in claim 4, wherein a tin layer is formed on the top surface, the bottom surface and the two opposite side surfaces of each lead; and
the end surface of each lead is formed by cutting and not covered by the tin layer.

9. The flat semiconductor package as claimed in claim 5, wherein the multiple leads protrude from two opposite ones of the four side surfaces of the encapsulant layer.

10. The flat semiconductor package as claimed in claim 6, wherein the multiple leads protrude from two opposite ones of the four side surfaces of the encapsulant layer.

11. The flat semiconductor package as claimed in claim 7, wherein the multiple leads protrude from two opposite ones of the four side surfaces of the encapsulant layer.

12. The flat semiconductor package as claimed in claim 8, wherein the multiple leads protrude from two opposite ones of the four side surfaces of the encapsulant layer.

13. The flat semiconductor package as claimed in claim 5, wherein a metal heat dissipation layer is formed over the top surface of the encapsulant layer.

14. The flat semiconductor package as claimed in claim 6, wherein a metal heat dissipation layer is formed over the top surface of the encapsulant layer.

15. The flat semiconductor package as claimed in claim 7, wherein a metal heat dissipation layer is formed over the top surface of the encapsulant layer.

16. The flat semiconductor package as claimed in claim 8, wherein a metal heat dissipation layer is formed over the top surface of the encapsulant layer.

17. The flat semiconductor package as claimed in claim 8, wherein each of the multiple leads and the die pad have the same thickness.
